(19) United States
(12) Patent Application Publication
(10) Pub. No.: US 2026/0269559 A1
(43) Pub. Date: Sep. 10, 2026

(54) ELECTRONIC DEVICE

(71) Applicant: Sony Semiconductor Solutions Corporation, Kanagawa (JP)

(72) Inventor: Takashi IMAHIGASHI, Kumamoto (JP)

(21) Appl. No.: 18/995,008

(22) PCT Filed: Jul. 4, 2023
(86) PCT No.: PCT/JP2023/024719

§ 371 Date: Jan. 15, 2025

(30) Foreign Application Priority Data
Aug. 2, 2022 (JP) 2022-123436

(51) Int. Cl. H01S 5/02; H01S 5/02253; H01S 5/042

(52) U.S. Cl. CPC H01S 5/0216; H01S 5/04257; H01S 5/02253

(57) ABSTRACT

An electronic device according to an embodiment includes a chip, a semiconductor substrate, bumps, an insulating film, and a metal film. The chip is provided with a semiconductor laser. The semiconductor substrate is provided with a drive circuit that drives the semiconductor laser. The bumps respectively connect a plurality of chip-side connection pads provided on a principal surface of the chip opposite to an emission surface of laser light, and a plurality of substrate-side connection pads provided on a principal surface of the semiconductor substrate on the side opposing the chip. The insulating film is provided in the same layer as the substrate-side connection pads, and insulates between the adjacent substrate-side connection pads. The metal film is provided on the insulating film.

### FIELD

The present disclosure relates to an electronic device.

### BACKGROUND

There is an electronic device including a semiconductor substrate provided with a drive circuit that drives a semiconductor laser, and a chip stacked on the semiconductor substrate via a bump and provided with a semiconductor laser, the electronic device emitting laser light from a principal surface of the chip, the principal surface not opposing the semiconductor substrate (for example, Patent Literature 1).

### CITATION LIST

### Patent Literature

Patent Literature 1: JP 2022-519186 A

### SUMMARY

### Technical Problem

However, in the electronic device that emits the laser light from the principal surface, which does not oppose the semiconductor substrate, of the chip, the operation of the drive circuit is adversely affected if the laser light emitted from the chip is irregularly reflected by a lens provided on the chip and is incident on the drive circuit.

Therefore, the present disclosure proposes an electronic device capable of suppressing reflected light of laser light from being incident on a drive circuit.

### Solution to Problem

An electronic device according to an embodiment includes a chip, a semiconductor substrate, bumps, an insulating film, and a metal film. The chip is provided with a semiconductor laser. The semiconductor substrate is provided with a drive circuit that drives the semiconductor laser. The bumps respectively connect a plurality of chip-side connection pads provided on a principal surface of the chip opposite to an emission surface of laser light, and a plurality of substrate-side connection pads provided on a principal surface of the semiconductor substrate on the side opposing the chip. The insulating film is provided in the same layer as the substrate-side connection pads, and insulates between the adjacent substrate-side connection pads. The metal film is provided on the insulating film.

### BRIEF DESCRIPTION OF DRAWINGS

FIG. 1 is an explanatory cross-sectional view of an electronic device according to an embodiment of the present disclosure.

FIG. 2 is an explanatory cross-sectional view taken along line A-A of the electronic device according to the embodiment of the present disclosure.

FIG. 3 is an explanatory view illustrating a manufacturing process of a semiconductor substrate according to the embodiment of the present disclosure.

FIG. 4 is an explanatory view illustrating the manufacturing process of the semiconductor substrate according to the embodiment of the present disclosure.

FIG. 5 is an explanatory view illustrating the manufacturing process of the semiconductor substrate according to the embodiment of the present disclosure.

FIG. 6 is an explanatory view illustrating the manufacturing process of the semiconductor substrate according to the embodiment of the present disclosure.

FIG. 7 is an explanatory view illustrating the manufacturing process of the semiconductor substrate according to the embodiment of the present disclosure.

FIG. 8 is an explanatory view illustrating the manufacturing process of the semiconductor substrate according to the embodiment of the present disclosure.

FIG. 9 is an explanatory view illustrating the manufacturing process of the semiconductor substrate according to the embodiment of the present disclosure.

FIG. 10 is an explanatory view illustrating the manufacturing process of the semiconductor substrate according to the embodiment of the present disclosure.

FIG. 11 is an explanatory view illustrating a manufacturing process of a chip according to the embodiment of the present disclosure.

FIG. 12 is an explanatory view illustrating the manufacturing process of the chip according to the embodiment of the present disclosure.

FIG. 13 is an explanatory view illustrating the manufacturing process of the chip according to the embodiment of the present disclosure.

FIG. 14 is an explanatory view illustrating the manufacturing process of the chip according to the embodiment of the present disclosure.

### DESCRIPTION OF EMBODIMENTS

Hereinafter, embodiments of the present disclosure will be described in detail with reference to the drawings. Note that the same portions are denoted by the same reference signs and the same hatching in each of the following embodiments, and a repetitive description thereof will be omitted.

### 1. Cross-Sectional Structure of Electronic Device

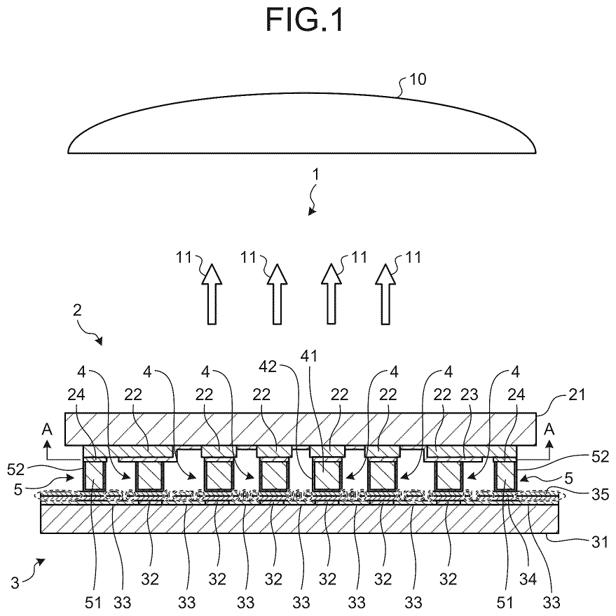

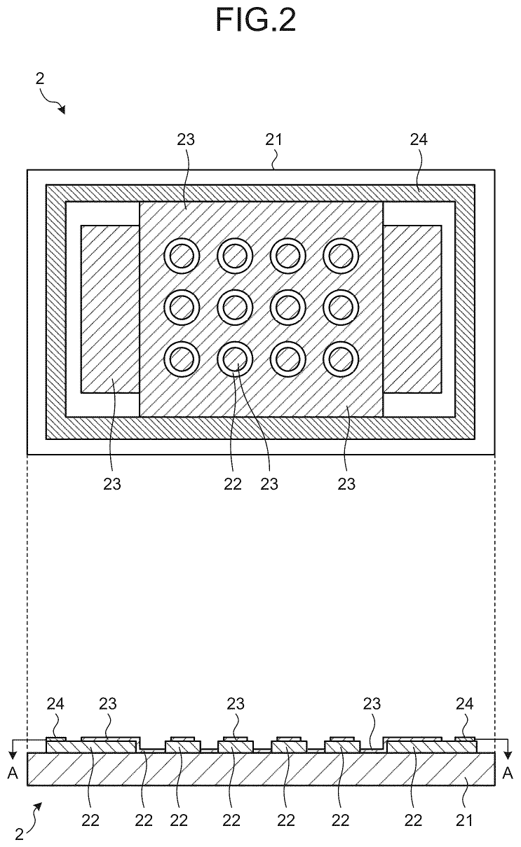

FIG. 1 is an explanatory cross-sectional view of an electronic device according to an embodiment of the present disclosure. FIG. 2 is an explanatory cross-sectional view taken along line A-A illustrated in FIG. 1. As illustrated in FIG. 1, an electronic device 1 according to the present disclosure includes a chip 2, a semiconductor substrate 3, bumps 4, insulating films 33, and metal films 34 and 35.

The chip 2 is provided with a semiconductor laser inside a base material 21, for example, of GaAs (gallium arsenide). Note that the base material of the chip 2 may be, for example, a semi-insulating base material such as InP (indium phosphide).

In addition, the chip 2 is provided with a plurality of chip-side connection pads (hereinafter, referred to as “connection pads 22”) on one principal surface (in FIG. 1, a lower surface) of the base material 21. The respective connection pads 22 are connected to light emitting elements of the semiconductor laser. A metal film 23 is provided between each of the connection pads 22 and each of the bumps 4. The metal film 23 is made of, for example, gold (Au).

The semiconductor substrate 3 includes, for example, a Si (silicon) substrate 31. A drive circuit that drives the semiconductor laser is provided inside the Si substrate 31. The semiconductor substrate 3 is provided with a plurality of substrate-side connection pads (hereinafter, referred to as “connection pads 32”) on one principal surface (in FIG. 1, an upper surface). The connection pads 32 are connected to the drive circuit inside the semiconductor substrate 3. Note that an electronic circuit included in the semiconductor substrate 3 may be any electronic circuit other than the drive circuit of the semiconductor laser.

The bumps 4 connect the plurality of connection pads 22 provided on the principal surface of the chip 2 opposite to an emission surface of laser light 11 and the plurality of connection pads 32 provided on the principal surface of the semiconductor substrate 3 on the side opposing the chip 2.

Each of the bumps 4 includes a porous metal layer 41 and a metal film 42 covering a side surface and a bottom surface of the porous metal layer 41. The porous metal layer 41 and the metal film 42 are made of, for example, gold (Au). Each of the insulating films 33 is provided in the same layer as the connection pads 32 and insulates between the adjacent connection pads 32. The insulating film 33 is made of, for example, SiN (silicon nitride).

The electronic device 1 emits the laser light 11 upward from the other principal surface (in FIG. 1, an upper surface) of the chip 2. The electronic device 1 includes a lens 10 that is provided above the chip 2 to deflect and diverge the laser light 11 emitted from each of the light emitting elements and emit the deflected and diverged laser light.

For this reason, in the electronic device 1, the laser light 11 emitted from the chip 2 may be irregularly reflected by the lens 10 and incident on the semiconductor substrate 3. If the laser light 11 is incident on the drive circuit provided inside the semiconductor substrate 3, the operation of the drive circuit is adversely affected. For example, if reflected light of the laser light 11 is incident to the drive circuit from the outside, a value of a current flowing through the circuit may change, an output of the laser may change, control may change, and malfunction may occur.

Therefore, the metal films 34 and 35 are provided on the insulating films 33 in the electronic device 1. The metal film 34 is made of, for example, Ti (titanium). The metal film 34 is provided on the insulating films 33. The metal film 35 is made of, for example, Au (gold). The metal film 35 is provided on the metal film 34.

As a result, even if the reflected light of the laser light 11 passes through the chip from, for example, a gap between the connection pads 22 in the chip 2, the electronic device 1 can suppress the reflected light of the laser light 11 from being incident on the drive circuit by the metal films 34 and 35.

In addition, the metal films 34 and 35 provided on the insulating films 33 are made of the same types of metal as those of the metal films 34 and 35 provided between the connection pad 32 and the bump 4, respectively, and are provided in the same layers as the metal films 34 and 35 provided between the connection pad 32 and the bump 4, respectively.

As a result, the metal films 34 and 35 provided on the insulating films 33 are simultaneously formed in a process of forming the metal films 34 and 35 provided between the connection pad 32 and the bump 4. Therefore, the metal films 34 and 35 provided on the insulating films 33 can be easily formed only by changing a pattern of a glass mask for patterning the metal films 34 and 35 without adding a special manufacturing process.

In addition, in the metal films 34 and 35 provided between the connection pad 32 and the bump 4, the area of a face parallel to the principal surface of the semiconductor substrate 3 is larger than the area of a cross section of the bump 4, the cross section being parallel to the principal surface of the semiconductor substrate 3. As a result, the metal films 34 and 35 provided between the connection pad 32 and the bump 4 can prevent the reflected light from being incident on the semiconductor substrate 3 from sides of the bump 4.

In addition, the metal films 34 and 35 provided on the insulating film 33 and the metal films 34 and 35 provided between the connection pad 32 and the bump 4 are separated by a slit. As a result, the electronic device 1 can prevent a short circuit between the connection pads 32 via the metal films 34 and 35.

Furthermore, the electronic device 1 includes a side wall portion 5 that annularly surrounds a region where the plural bumps 4 are provided. The side wall portion 5 connects the chip 2 and the semiconductor substrate 3. The side wall portion 5 includes a porous metal layer 51 and a metal film 52 covering a bottom surface and a side surface of the porous metal layer 51. The porous metal layer 51 and the metal film 52 are made of, for example, gold (Au).

Further, the metal films 34 and 35 provided on the insulating films 33 are made of the same types of metal as those of the metal films 34 and 35 provided between the side wall portion 5 and the semiconductor substrate 3, respectively, and are provided in the same layers as the metal films 34 and 35 provided between the side wall portion 5 and the semiconductor substrate 3, respectively.

As a result, the metal films 34 and 35 provided on the insulating films 33 are simultaneously formed in a process of forming the metal films 34 and 35 provided between the side wall portion 5 and the semiconductor substrate 3. Therefore, the metal films 34 and 35 provided on the insulating films 33 can be easily formed only by changing a pattern of a glass mask for patterning the metal films 34 and 35 without adding a special manufacturing process.

In addition, in the metal films 34 and 35 provided between the side wall portion 5 and the semiconductor substrate 3, the area of a face parallel to the principal surface of the semiconductor substrate 3 is larger than the area of a cross section of the side wall portion 5, the cross section being parallel to the principal surface of the semiconductor substrate 3. As a result, the metal films 34 and 35 provided between the side wall portion 5 and the semiconductor substrate 3 can prevent the reflected light from being incident on the semiconductor substrate 3 from sides of the side wall portion 5.

In addition, the metal films 34 and 35 provided between the side wall portion 5 and the semiconductor substrate 3 are connected to the ground. As a result, the electronic device 1 can discharge electric charge accumulated in a parasitic capacitance, generated due to the metal films 34 and 35 provided between the side wall portion 5 and the semiconductor substrate 3, to the ground, and can reduce electro-magnetic interference (EMI) noise.

In the electronic device 1, the chip 2 is flip-chip mounted on the semiconductor substrate 3, and the drive circuit in the semiconductor substrate 3 and the chip 2 including the semiconductor laser are electrically connected by the bumps 4. In addition, in the electronic device 1, a space in which the connection pads 22 and 32 and the bumps 4 are provided is hermetically sealed by the side wall portion 5.

Here, for example, in a case where an electronic device is manufactured by flip-chip mounting the chip 2 including a semiconductor laser on the semiconductor substrate 3 including a drive circuit for the semiconductor laser, a plurality of the drive circuits is first formed on a Si wafer in a general manufacturing method.

Thereafter, the chip 2 is stacked on the respective drive circuits via a bulk-shaped metal bump, and the connection pads 22 and 32 provided on the opposing principal surfaces of the drive circuit and the chip 2, respectively, are connected to each other by the bump. Then, the Si wafer is diced into individual pieces for each electronic device.

In a process of dividing the Si wafer into individual pieces for each of the electronic devices, dicing is performed while supplying cutting water to the Si wafer. At this time, the electronic devices are adversely affected if the cutting water enters between the semiconductor substrate 3 and the chip 2. Therefore, generally, each of the electronic devices is sealed with resin, and then, the Si wafer is divided into individual pieces for each of the electronic devices.

However, in a case where the electronic device is sealed with the resin, there are problems such as contamination of an electrode by the resin, prolongation of working time due to injection of the resin for each of the electronic devices, and an increase in the amount of resin discarded after the period of use due to the prolongation of working time.

For this reason, there is a technique in which the connection pads 22 and 32 respectively provided on the opposing principal surfaces of the semiconductor substrate 3 and the chip 2 are connected by the bump, and a region in which the connection pads 22 and 32 and the bump are provided and which needs to be sealed is boned and sealed using the same connection method as the connection between the connection pads 22 and 32.

In addition, in the general flip-chip mounting, the chip 2 is mounted on the semiconductor substrate 3 by heating the metal bump such as bulk-shaped Au (gold), Cu (copper), or solder provided on the opposing principal surface of the semiconductor substrate 3 or the chip 2 while pressing the bump.

However, in a case where thermal expansion coefficients of the semiconductor substrate 3 and the chip 2 are different from each other by, for example, 0.1 ppm/° C. or more, the following problems occur when bulk-shaped Au, Cu, or solder is used as a material of the bump.

For example, when bulk-shaped Au is used as the material of the bump, it is necessary to perform heating at a high temperature of 300° C. or higher and apply a high pressure of 100 MPa or more between the semiconductor substrate 3 and the chip 2 in order to stably connect the semiconductor substrate 3 and the chip 2 having different thermal expansion coefficients by the bump.

In addition, when bulk-shaped Cu is used as the material of the bump, it is necessary to perform heating at 380° C. or higher. In this manner, when bulk-shaped Au or Cu is used as the material of the bump, it is necessary to perform the connection by the bump at a high temperature and a high pressure, and the high temperature and the high pressure may damage the chip 2, and the reliability of the electronic device may be lowered.

On the other hand, when solder is used as the material of the bump, the connection by the bump can be performed at a low temperature and a low pressure as compared with Au and Cu, but solder is inferior in heat resistance and connection strength to Au and Cu. For this reason, when the chip 2 is thermally expanded due to heat generation of an electronic component such as the semiconductor laser mounted on the chip 2, for example, there is a possibility that open failure occurs due to a difference in the thermal expansion coefficient between the semiconductor substrate 3 and the chip 2, and the bump made of solder lowers the reliability of the electronic device.

In addition, as described above, the semiconductor substrate 3 according to the present disclosure is the Si substrate, and has the thermal expansion coefficient of 5.7 ppm/ °C. On the other hand, the base material of the chip 2 according to the present disclosure is GaAs and has the thermal expansion coefficient of 2.6 ppm/° C.

In this manner, the difference in the thermal expansion coefficient between the semiconductor substrate 3 and the chip 2 is much larger than 0.1 ppm/° C. in the electronic device 1. For this reason, when the material of the bump is bulk-shaped Au, Cu, or solder in the electronic device 1, there is a possibility that the above problems occur and the reliability is lowered.

In addition, in a case where a peripheral edge portion of the region that needs to be sealed between the semiconductor substrate 3 and the chip 2 is surrounded, bonded, and sealed by bulk-shaped metal having a plated surface, a crack occurs in a sealed portion when the difference in the thermal expansion coefficient between the semiconductor substrate 3 and the chip 2 is, for example, 0.1 ppm/° C. or more. As a result, airtightness of the electronic device is deteriorated.

Furthermore, if the semiconductor substrate 3 or the chip 2 has a variation in thickness or warpage, the semiconductor substrate 3 and the chip 2 can be bonded only at a protrusion of a convex surface of a plating film in a sealed portion when the semiconductor substrate 3 and the chip 2 are stacked.

As a result, gaps are scattered in the sealed portion so that the airtightness of the electronic device is deteriorated. In addition, if the semiconductor substrate 3 and the chip 2 are bonded by increasing the temperature and pressure in order to prevent generation of a gap in the sealed portion, there is a possibility that short-circuit failure occurs between adjacent fine bumps in the electronic device.

Therefore, the bump 4 of the electronic device 1 includes, for example, the porous metal layer 41 of Au.

The porous metal layer 41 contains Au particles having a particle diameter of 0.005 μm to 1.0 μm and a purity of 99.9 wt % or more. Note that a component of the porous metal layer 41 may be, for example, Cu, Ag (silver), or Pt (platinum) having a purity of 99.9 wt % or more.

The porous metal layer 41 containing metal particles having a particle diameter of 0.005 μm to 1.0 μm can be metal-bonded at a temperature lower than a melting point of the bulk-shaped metal due to the size effect of the particle diameter. For example, the porous metal layer 41 can connect the semiconductor substrate 3 and the chip 2 at a temperature of about 100° C., 250° C., and 150° C. when the component is Au, Ag, and Cu, respectively. As a result, the electronic device 1 can reduce the damage to the chip 2 due to heat, and thus can improve the reliability.

In addition, the porous metal layer 41 has elasticity, and thus is elastically deformed, for example, even if the chip 2 expands with a thermal expansion coefficient different from that of the semiconductor substrate 3 due to heat generation of the semiconductor laser, so that it is possible to suppress the occurrence of the open failure. As a result, the electronic device 1 can improve the reliability as compared with, for example, a case where the bump made of solder is used.

The electronic device 1 is manufactured by stacking the chip 2 on the semiconductor substrate 3 provided with the bumps 4 on the upper surface and connecting the porous metal layers 41 of the bumps 4 to the connection pads 22 without melting to flip-chip mount the chip 2 on the semiconductor substrate 3.

In addition, the electronic device 1 may be manufactured by stacking the chip 2, provided with the bumps 4 each including the porous metal layer 41 on the lower surface, on the semiconductor substrate 3 and connecting the porous metal layers 41 of the bumps 4 to the connection pads 32 without melting to flip-chip mount the chip 2 on the semiconductor substrate 3. Note that the bump 4 including the porous metal layer 41 may be provided on both the semiconductor substrate 3 and the chip 2 before being stacked.

In the case of being provided on the semiconductor substrate 3 side, the bump 4 includes the metal film 42 between the porous metal layer 41 and the connection pad 32 on the semiconductor substrate 3 side. In addition, in the case of being provided on the chip 2 side, the bump 4 includes the metal film 42 between the porous metal layer 41 and the connection pad 22 on the chip 2 side. Note that the metal film 42 may be provided at least one of between the porous metal layer 41 and the connection pad 32 on the semiconductor substrate 3 side or between the porous metal layer 41 and the connection pad 22 on the chip 2 side.

In the present disclosure, it is possible to achieve a fine pitch in which the pitch of the bumps 4 is 20 μm or less by setting the proportion of a film thickness of the metal film 42 to a thickness of the bumps 4 in a direction orthogonal to the principal surface of the semiconductor substrate 3 to less than 10% Such a fine pitch will be described later together with a process of forming the bumps 4.

Furthermore, the bump 4 also includes the metal film 42 on the side surface (side peripheral surface) of the porous metal layer 41. A material of the metal film 42 is desirably the same as that of the porous metal layer 41. For example, when the material of the porous metal layer 41 is Au, the metal film 42 is desirably an Au film.

As a result, since the side surface of the porous metal layer 41 is coated with the metal film 42, the bump 4 can prevent the particles of the porous metal layer 41 from collapsing and scattering. Therefore, the bumps 4 can prevent the adjacent bumps 4 from being short-circuited by the scattering of the particles of the porous metal layer 41.

In addition, in a case where the metal film 42 is not provided on the side surface of the porous metal layer 41, surface roughness occurs on the side surface of the porous metal layer 41 whose surface is relatively soft so that the shape varies among the bumps 4.

On the other hand, since the metal film 42 harder than the porous metal layer 41 is provided on the side surface of the porous metal layer 41 in the bump 4, all the bumps 4 have a uniform shape with the variations in the shape being suppressed. Moreover, since the side surface of the bump 4 is coated with the relatively hard metal film 42, further miniaturization becomes possible, and a still finer pitch can be achieved.

In addition, the bump 4 is slightly crushed in the thickness direction when the chip 2 is flip-chip mounted on the semiconductor substrate 3, but prevents the particles of the porous metal layer 41 from leaking to the outside of the metal film 42. As a result, in the bump 4, the particle density of the porous metal layer 41 inside the metal film 42 increases, so that connection resistance can be reduced.

In addition, the side wall portion 5 of the electronic device 1 has a similar structure as the bump 4. Specifically, the side wall portion 5 includes the porous metal layer 51 of Au. The porous metal layer 51 contains Au particles having a particle diameter of 0.005 μm to 1.0 um and a purity of 99.9 wt % or more. Note that a component of the porous metal layer 51 may be, for example, Cu, Ag (silver), or Pt (platinum) having a purity of 99.9 wt % or more.

As described above, the porous metal layer 51 can be metal-bonded at a temperature lower than a melting point of bulk-shaped metal due to the size effect of the particle diameter. As a result, the electronic device 1 can reduce damage to the chip 2 due to heat at the time of formation of the porous metal layer 51, and thus can improve the reliability.

In addition, the porous metal layer 51 has elasticity, and thus is elastically deformed, for example, even if the chip 2 expands with a thermal expansion coefficient different from that of the semiconductor substrate 3 due to heat generation of the semiconductor laser, so that it is possible to suppress the occurrence of a crack in the side wall portion 5. As a result, the electronic device 1 can improve the airtightness of the region in which the connection pads 22 and 32 and the bumps 4 are provided and which needs to be sealed.

In addition, the porous metal layer 51 is elastically deformed, and thus is deformed following a surface shape of the semiconductor substrate 3 or the chip 2 when the semiconductor substrate 3 and the chip 2 are bonded even if the semiconductor substrate 3 or the chip 2 has a variation in thickness or warpage.

As a result, the electronic device 1 can suppress generation of gaps at a connection portion between the side wall portion 5 and the semiconductor substrate 3 and a connection portion between the side wall portion 5 and the chip 2, and thus can improve the airtightness.

In addition, the side wall portion 5 is provided so as to annularly surround the region in which the connection pads 22 and 32 and the bumps 4 are provided and which needs to be sealed. As a result, when the semiconductor substrate 3 or the chip 2 thermally expands, the electronic device 1 can alleviate mechanical stress applied to the bumps 4 provided at corner portions.

Specifically, when the semiconductor substrate 3 or the chip 2 thermally expands, the amount of expansion and the amount of contraction due to temperature changes increase from the center of the principal surface of the semiconductor substrate 3 or the chip 2 toward a peripheral edge portion. Therefore, the mechanical stress is applied to the bumps 4 provided at the corner portions unless the side wall portion 5 is provided.

On the other hand, in the electronic device 1, since the peripheral edge portions of the semiconductor substrate 3 and the chip 2 are sealed by the side wall portion 5, expansion and contraction of the peripheral edge portions of the semiconductor substrate 3 and the chip 2 due to temperature changes can be suppressed by the side wall portion 5. As a result, the electronic device 1 can alleviate the mechanical stress applied to the bumps 4 provided at the corner portions.

In the case of being provided on the semiconductor substrate 3 side, the side wall portion 5 includes the metal film 52 between the porous metal layer 51 and the connection pad 32 on the principal surface of the semiconductor substrate 3. In addition, in the case of being provided on the chip 2 side, the side wall portion 5 includes the metal film 52 between the porous metal layer 51 and the connection pad on the principal surface of the chip 2. Note that the metal film 52 may be provided at least one of between the porous metal layer 51 and the connection pad 32 on the principal surface of the semiconductor substrate 3 or between the porous metal layer 51 and the connection pad on the principal surface of the chip 2.

In the present disclosure, it is possible to achieve the fine pitch in which the pitch of the bumps 4 is 20 μm or less in a process of simultaneously forming the side wall portion 5 and the bumps 4 by setting the proportion of a film thickness of the metal film 52 to a thickness of the side wall portion 5 in the direction orthogonal to the principal surface of the semiconductor substrate 3 to less than 10%.

Furthermore, the side wall portion 5 also includes the metal film 52 on the side surface (side peripheral surface) of the porous metal layer 51. A material of the metal film 52 is desirably the same as that of the porous metal layer 51. For example, when the material of the porous metal layer 51 is Au, the metal film 52 is desirably an Au film.

As a result, since the side surface of the porous metal layer 51 is coated with the metal film 52, the side wall portion 5 can prevent the particles of the porous metal layer 51 from collapsing and scattering. Therefore, the side wall portion 5 can prevent the adjacent bumps 4 from being short-circuited due to the scattering of the particles of the porous metal layer 51.

In addition, in a case where the metal film 52 is not provided on the side surface of the porous metal layer 51, surface roughness occurs on the side surface of the porous metal layer 51 whose surface is relatively soft so that a side surface shape of the side wall portion 5 varies.

On the other hand, since the metal film 52 harder than the porous metal layer 51 is provided on the side surface of the porous metal layer 51 in the side wall portion 5, the variations in the side surface shape are Suppressed, and all the side surfaces have a uniform surface shape. Moreover, since the side surface of the side wall portion 5 is coated with the relatively hard metal film 52, further miniaturization becomes possible.

The electronic device 1 is manufactured by stacking the chip 2 not provided with the bumps 4 on the semiconductor substrate 3 provided with the bumps 4 on the upper surface and connecting the porous metal layers 41 of the bumps 4 to the connection pads 22 without melting to flip-chip mount the chip 2 on the semiconductor substrate 3.

In addition, the electronic device 1 may be manufactured by stacking the chip 2, provided with the bumps 4 each including the porous metal layer 41 on the lower surface, on the semiconductor substrate 3 not provided with the bumps 4 and connecting the porous metal layers 41 of the bumps 4 to the connection pads 32 without melting to flip-chip mount the chip 2 on the semiconductor substrate 3. Note that the bump 4 including the porous metal layer 41 may be provided on both the semiconductor substrate 3 and the chip 2 before being stacked.

### 2. Process of Forming Bumps and Side Wall Portion

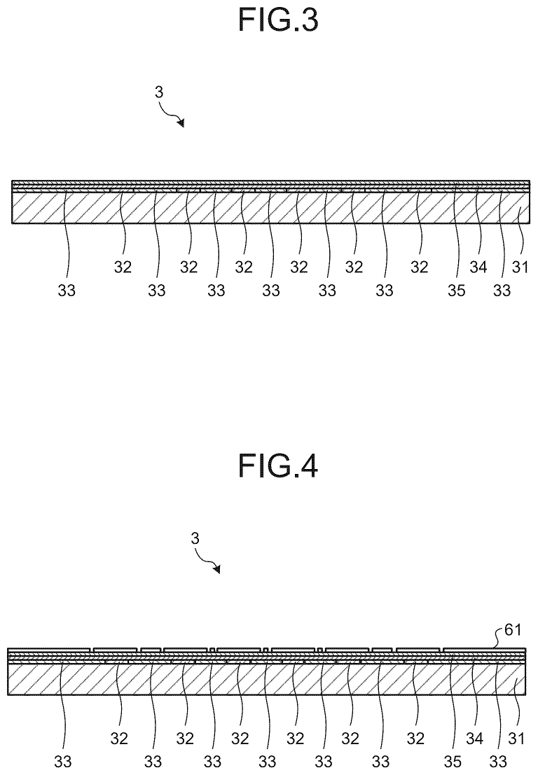

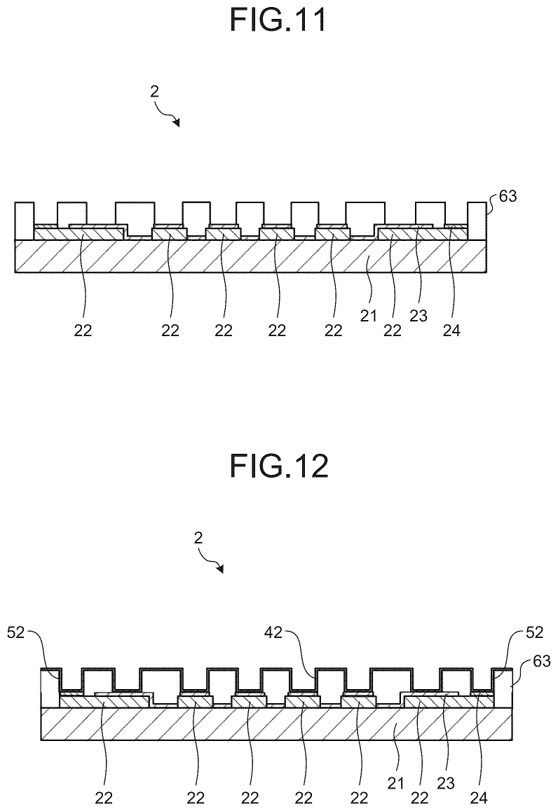

Next, a process of forming the electronic device 1 according to the present disclosure will be described with reference to FIGS. 3 to 14. FIGS. 3 to 10 are explanatory views illustrating a manufacturing process of the semiconductor substrate 3 according to the present disclosure. FIGS. 11 to 14 are explanatory views illustrating a manufacturing process of the chip 2 according to the present disclosure.

As illustrated in FIG. 3, in the case of manufacturing the semiconductor substrate 3, first, the connection pads 32 are formed at predetermined positions on the Si substrate 31, and the insulating films 33 are formed in regions other than the positions where the connection pads 32 are formed on the Si substrate 31. Thereafter, the metal film 34 and the metal film 35 are sequentially laminated on the connection pads 32 and the insulating films 33.

Subsequently, as illustrated in FIG. 4, a glass mask 61 is stacked on the metal film 35, and the glass mask 61 in portions corresponding to locations other than regions where the metal films 34 and 35 are to remain are removed to form slits in the glass mask 61.

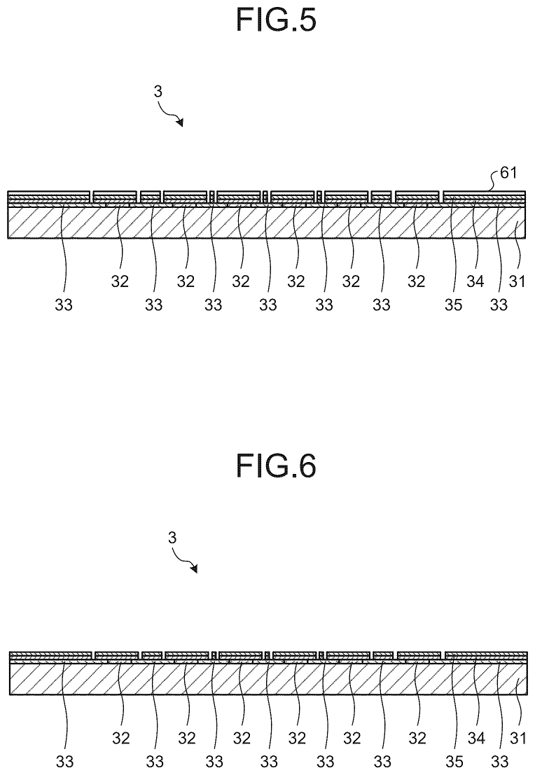

Then, as illustrated in FIG. 5, for example, dry etching is performed through the remaining glass mask 61 to remove the metal films 34 and 35 in portions on which the glass mask 61 is not stacked. Thereafter, the glass mask 61 is removed as illustrated in FIG. 6.

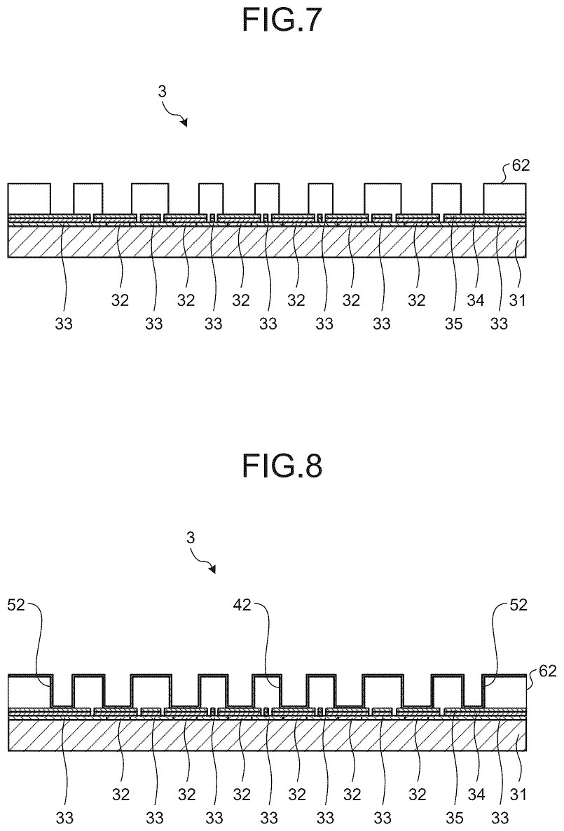

Subsequently, as illustrated in FIG. 7, a photoresist layer 62 is formed on the metal films 34 and 35, and then through-holes are formed at positions where the bumps 4 and the side wall portion 5 are to be formed in the photoresist layer 62 by a photolithography technique to expose surfaces of the metal films 34 and 35.

At this time, the through-holes are formed such that an interval between centers of adjacent through-holes is 20 μm (20 μm pitch). Such through-holes are filled with a paste containing metal particles to be the material of the porous metal layer 41 in a later process, but, due to a fine structure of 20 μm pitch, if the through-holes are filled with the paste in this state, there is a possibility that the fine structure is damaged and broken.

Therefore, as illustrated in FIG. 8, the metal films 42 and 52 are formed on an upper surface of the photoresist layer 62, side surfaces of the through-holes, and an upper surface of the metal film 35, for example, by sputtering. As the material of the metal films 42 and 52, metal having the same component as the metal particles contained in the paste with which the through-holes are to be filled later is selected. Note that the Au metal films 42 and 52 are formed here.

As a result, the photoresist layer 62 is cured by coating a surface thereof with the metal films 42 and 52, and thus can prevent the fine structure from collapsing when the through-holes are filled with the paste containing the metal particles.

In addition, if the thickness of the metal films 42 and 52 formed here is too thick, openings of the through-holes become narrow, and it becomes difficult to fill the through-holes with the paste containing the metal particles. Therefore, here, the metal films 42 and 52 that are thin (with, for example, a thickness of less than 1 μm) are formed such that the proportion of the film thickness of the metal films 42 and 52 to a depth of the through-hole, in other words, the thickness of the bump 4 (a height of the bumps 4) to be formed later in the direction orthogonal to the principal surface of the semiconductor substrate 3 is less than 10%.

For example, in the case of forming the bumps 4 having a height of 10 um arranged at a 20 μm pitch, the film thickness of the metal films 42 and 52 is set to 0.2 μm. As a result, even when the metal films 42 and 52 are formed, it is possible to prevent the openings of the through-holes from being narrowed, so that the through-holes can be sufficiently filled with the paste containing the metal particles in a later process.

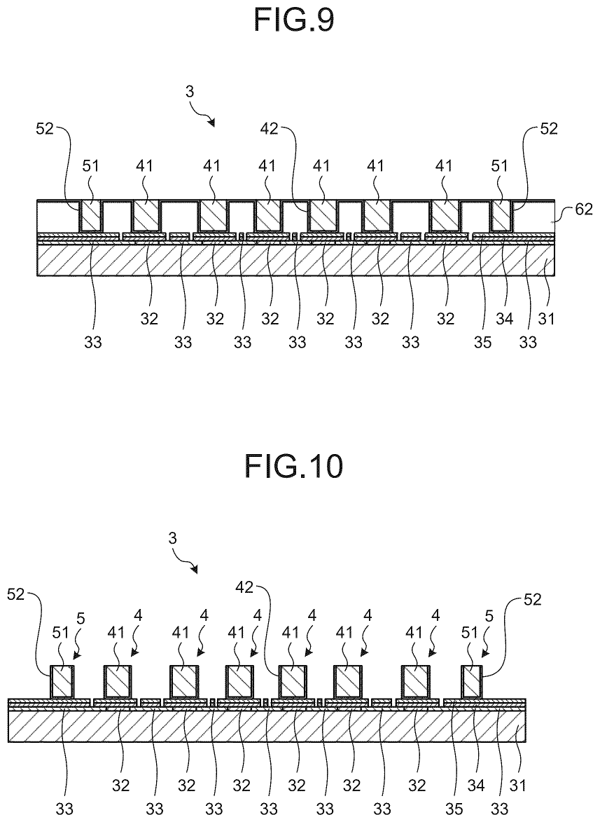

Subsequently, as illustrated in FIG. 9, the through-holes formed in the photoresist layer 62 are filled with, for example, the paste containing Au particles having a purity of 99.9 wt % or more and a particle diameter of 0.005 μm to 1.0 μm to form the porous metal layers 41 and 51. As a method of filling the through-holes with the paste, for example, any method such as screen printing or a method of spreading the dropped paste with a spatula can be used.

Thereafter, the paste is dried and sintered, and then the photoresist layer 62 is peeled off by lift-off using a peeling solution or the like. As a result, as illustrated in FIG. 10, the bumps 4 and the side wall portion 5 are formed on the semiconductor substrate 3.

Next, the manufacturing process of the chip 2 will be described. As illustrated in FIG. 11, in the case of manufacturing the chip 2, first, the connection pads 22 are formed at predetermined positions on the base material 21, and the metal films 23 and 24 are formed at portions where an upper surface of the base material 21 is exposed and predetermined positions on upper surfaces of the connection pads 22.

Then, a photoresist layer 63 is formed on a surface of the chip 2 on the side where the connection pads 22 and the metal films 23 and 24 are provided. Thereafter, through-holes are formed at positions where the bumps 4 and the side wall portion 5 are to be formed in the photoresist layer 63 by a photolithography technique to expose surfaces of the metal films 23 and 24.

Thereafter, as illustrated in FIG. 12, the metal films 42 and 52 are formed on an upper surface of the photoresist layer 63, side surfaces of the through-holes, and upper surfaces of the metal films 23 and 24, for example, by sputtering. As the material of the metal films 42 and 52, Au having the same component as Au particles contained in a paste with which the through-holes are to be filled later is selected.

As a result, the photoresist layer 63 is cured by coating a surface thereof with the metal films 42 and 52, and thus can prevent the fine structure from collapsing when the through-holes are filled with the paste containing the Au particles.

In addition, here, the metal films 42 and 52 that are thin (with, for example, a thickness of less than 1 μm) are also formed such that the proportion of the film thickness of the metal films 42 and 52 to a depth of the through-hole, in other words, the thickness of the bumps 4 (a height D1 of the bumps 4) to be formed later in the direction orthogonal to the principal surface of the chip 2 is less than 10%.

For example, in the case of forming the bumps 4 having a height of 10 μm arranged at a 20 μm pitch, the film thickness of the metal films 42 and 52 is set to 0.2 μm. As a result, even when the metal films 42 and 52 are formed, it is possible to prevent the openings of the through-holes from being narrowed, so that the through-holes can be sufficiently filled with the paste containing the metal particles in a later process.

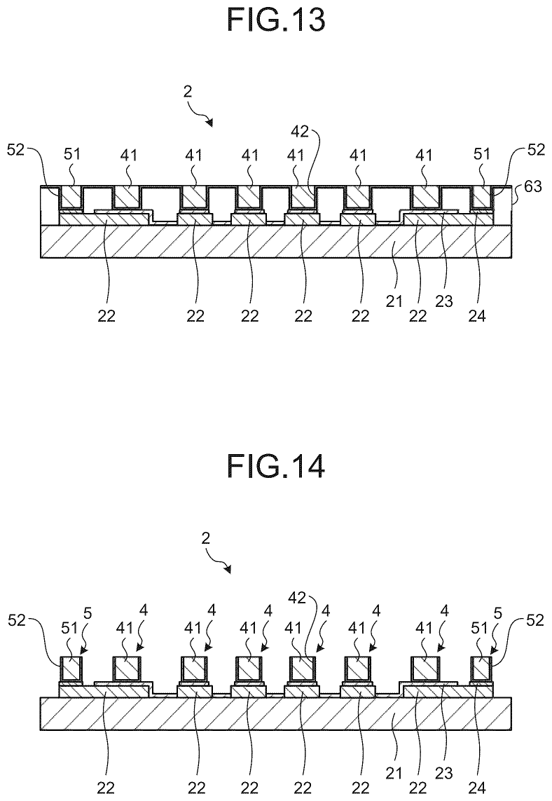

Subsequently, as illustrated in FIG. 13, the through-holes formed in the photoresist layer 63 are filled with, for example, the paste containing Au particles having a purity of 99.9 wt % or more and a particle diameter of 0.005 μm to 1.0 μm, thereby forming the bumps 4 and the side wall portion 5.

Thereafter, the paste is dried and sintered, and then the photoresist layer 63 is peeled off by lift-off using a peeling solution or the like. As a result, as illustrated in FIG. 14, the bumps 4 and the side wall portion 5 are formed on the chip 2.

Thereafter, the semiconductor substrate 3 illustrated in FIG. 10 and the chip 2 illustrated in FIG. 14 are arranged such that the respective connection pads 22 and 32 oppose each other, and the connection pads 22 are connected to each other, whereby the electronic device 1 illustrated in FIG. 1 is completed.

The chip 2 including the semiconductor laser and the semiconductor substrate 3 including the drive circuit for the semiconductor laser described above are mounted on a distance measuring device such as a ToF sensor or a structured light, for example. In a case where the semiconductor laser is mounted on the distance measuring device, for example, the semiconductor laser functions as a light source of the ToF sensor or a light source of the structured light.

Note that the effects described in the present specification are merely examples and are not restrictive of the disclosure herein, and other effects not described herein also can be achieved.

Note that the present technology can also have the following configurations.

(1)

An electronic device including:
a chip provided with a semiconductor laser;
a semiconductor substrate provided with a drive circuit that drives the semiconductor laser;
a plurality of bumps respectively connecting a plurality of chip-side connection pads provided on a principal surface of the chip opposite to an emission surface of laser light, and a plurality of substrate-side connection pads provided on a principal surface of the semiconductor substrate on a side facing the chip;
an insulating film that is provided in an identical layer with the substrate-side connection pads and insulates between adjacent substrate-side connection pads among the substrate-side connection pads; and
a metal film provided on the insulating film.
   (2)

The electronic device according to (1), wherein
the metal film
is made of a same type of metal as a metal film provided between each of the substrate-side connection pads and each of the bumps, and is provided in a same layer as the metal film provided between each of the substrate-side connection pads and each of the bumps.
   (3)

The electronic device according to (3), wherein
in the metal film provided between each of the substrate-side connection pads and each of the bumps,
an area of a face parallel to the principal surface is larger than an area of a cross section of the bump, the cross section being parallel to the principal surface.
   (4)

The electronic device according to (2) or (3), wherein
the metal film provided on the insulating film and the metal film provided between each of the substrate-side connection pads and each of the bumps are separated by a slit.
   (5)

The electronic device according to any one of (1) to (4), further including
a side wall portion provided to annularly surround a region where the plurality of bumps are provided, the side wall portion connecting the chip and the semiconductor substrate,
wherein the metal film provided on the insulating film
is made of a same type of metal as a metal film provided between the side wall portion and the semiconductor substrate, and is provided in a same layer as the metal film provided between the side wall portion and the semiconductor substrate.
   (6)

The electronic device according to (5), wherein
in the metal film provided between the side wall portion and the semiconductor substrate,
an area of a face parallel to the principal surface is larger than an area of a cross section of the side wall portion, the cross section being parallel to the principal surface.
   (7)

The electronic device according to any one of (1) to (6), wherein
the metal film provided on the insulating film includes
a titanium film provided on the insulating film and a gold film provided on the titanium film.

### REFERENCE SIGNS LIST

1 ELECTRONIC DEVICE
2 CHIP
3 SEMICONDUCTOR SUBSTRATE
4 BUMP
5 SIDE WALL PORTION
10 LENS
11 LASER LIGHT
21 BASE MATERIAL
22, 32 CONNECTION PAD
23, 24, 34, 35 METAL FILM
31 SI SUBSTRATE
33 INSULATING FILM
41 51 POROUS METAL LAYER
42, 52 METAL FILM
61 GLASS MASK
62 PHOTORESIST LAYER
63 PHOTORESIST LAYER

1. An electronic device comprising:
a chip provided with a semiconductor laser;
a semiconductor substrate provided with a drive circuit that drives the semiconductor laser;
a plurality of bumps respectively connecting a plurality of chip-side connection pads provided on a principal surface of the chip opposite to an emission surface of laser light, and a plurality of substrate-side connection pads provided on a principal surface of the semiconductor substrate on a side facing the chip;
an insulating film that is provided in an identical layer with the substrate-side connection pads and insulates between adjacent substrate-side connection pads among the substrate-side connection pads; and
a metal film provided on the insulating film.

2. The electronic device according to claim 1, wherein
the metal film
is made of a same type of metal as a metal film provided between each of the substrate-side connection pads and each of the bumps, and is provided in a same layer as the metal film provided between each of the substrate-side connection pads and each of the bumps.

3. The electronic device according to claim 2, wherein
in the metal film provided between each of the substrate-side connection pads and each of the bumps,
an area of a face parallel to the principal surface is larger than an area of a cross section of the bump, the cross section being parallel to the principal surface.

4. The electronic device according to claim 2, wherein
the metal film provided on the insulating film and the metal film provided between each of the substrate-side connection pads and each of the bumps are separated by a slit.

5. The electronic device according to claim 1, further comprising
a side wall portion provided to annularly surround a region where the plurality of bumps are provided, the side wall portion connecting the chip and the semiconductor substrate,
wherein the metal film provided on the insulating film
is made of a same type of metal as a metal film provided between the side wall portion and the semiconductor substrate, and is provided in a same layer as the metal film provided between the side wall portion and the semiconductor substrate.

6. The electronic device according to claim 5, wherein
in the metal film provided between the side wall portion and the semiconductor substrate,
an area of a face parallel to the principal surface is larger than an area of a cross section of the side wall portion, the cross section being parallel to the principal surface.

7. The electronic device according to claim 1, wherein
the metal film provided on the insulating film includes
a titanium film provided on the insulating film and a gold film provided on the titanium film.
